(19) United States
(12) Patent Application Publication
(10) Pub. No.: US 2023/0179411 A1
(43) Pub. Date: Jun. 8, 2023

(54) ENTROPY GENERATION FOR USE IN CRYPTOGRAPHIC RANDOM NUMBER GENERATION

(71) Applicant: Rambus Inc., San Jose, CA (US)

(72) Inventor: Marcel Van Loon, Oss (NL)

(21) Appl. No.: 17/916,772

(22) PCT Filed: Apr. 7, 2021
(86) PCT No.: PCT/US2021/026278

§ 371 Date: Oct. 3, 2022

Related U.S. Application Data
(60) Provisional application No. 63/045,656, filed on Jun. 29, 2020.
(60) Provisional application No. 63/007,607, filed on Apr. 9, 2020.

(51) Int. Cl. H04L 9/08; G06F 7/58; H03K 3/03

(52) U.S. Cl. CPC H04L 9/0869; G06F 7/588; H03K 3/0315

(57) ABSTRACT

The embodiments described herein describe technologies of a latch-based freerunning oscillator (FRO). The latch-based FROs can be used to generate a random digital value. The entropy of the random digital value is based on the free-running oscillation of the latch-based FRO, as well as the metastability of the latches. The random digital value can be part of an N-bit random number.

### BACKGROUND

Various applications utilize a random number generator (RNG) to generate a sequence of numbers that lack any predictable pattern. There are many applications of randomness and there are several different methods for generating random data. It should be noted that several computational methods for random number generation exist, but many fall short of “true” randomness. Rather these methods may meet, with varying success, some of the statistical tests for randomness intended to measure how unpredictable their results are. That is, to what degree their patterns are discernible. The uncertainty is often quantified in terms of “entropy,” a standard measure of unpredictability of information content.

A pseudorandom number generator (PRNG), also known as a deterministic random bit generator (DRBG), is an algorithm for generating a sequence of numbers whose properties approximate the properties of sequences of random numbers. The PRNG-generated sequence is not truly random, because it is completely determined by a relatively small set of initial values, called the PRNG's seed (which may include truly random values). Although sequences that are closer to truly random can be generated using specialized hardware (e.g., ones based on quantum-mechanical effects), pseudorandom number generators are important in practice for their speed in number generation, and their practicality for being implemented in low-cost compute systems. Cryptographic systems need a good source of randomness, for example, to be used for key generation or cryptographic challenges. There are cryptographically secure computationally based methods of generating random numbers, such as, for example, those based on the Yarrow algorithm and the Fortuna (PRNG), and others. Cryptographically strong PRNGs may be seeded by many independent sources of uncertainty, some of which may be under an attacker's control. A good seed source may be a true random number generator (TRNG), which is tied to some known-random physical phenomena (e.g., offset, thermal noise, phase noise, or the like). A sequence of numbers from a chaotic (as opposed to random) generator is similar to PRNGs in that it is deterministic, rule-based, and evolves predictably from an initial state.

### BRIEF DESCRIPTION OF THE DRAWINGS

The present disclosure is illustrated by way of example, and not by way of limitation, in the figures of the accompanying drawings.

FIG. 1 is a schematic diagram of an integrated circuit with a latch-based free-running oscillator (FRO) to generate a random digital value according to one embodiment.

FIG. 2 is a schematic diagram of a FRO with a set of latches organized in a looping sequence to generate a random digital value according to one embodiment.

FIG. 3 is a schematic diagram of an output circuit coupled to a FRO with a set of latches according to one embodiment.

FIG. 4A is a schematic diagram of a conventional, inverter-based FRO and a single sampling circuit according to one implementation.

FIG. 4B is a schematic diagram of an inverter-based FRO and multiple sampling circuits according to another implementation.

FIG. 5 is a schematic diagram of a digital RNG including two N-bit FROs according to one embodiment.

FIG. 6 is a flow diagram of a method of generating a random digital value using a latch-based FRO according to one embodiment.

FIG. 7 is a flow diagram of a method of generating a random digital value using a latched-based FRO according to another embodiment.

FIG. 8 is a block diagram of an electronic device, including a RNG with a latch-based FRO for a cryptographic operation of a cryptographic process according to one embodiment.

### DETAILED DESCRIPTION

The embodiments described herein describe technologies of a free-running oscillator (FRO) with latches, instead of inverters, and an output circuit for capturing a complete state of the FRO. The FRO and output circuit can be used to form an N-bit, random number generator (RNG) to generate a random value using an entirely digital circuit design methodology. The FRO can generate a cyclic pattern, which, as time progresses, exhibits an increasingly unpredictable error on the phase of the cyclic pattern. Each latch in an “open state,” acts as an inverter and the latches collectively create a FRO state with the outputs of all of the latches. That is, an output of each latch, also referred to herein as a “tap,” can be input into a combinatorial circuit for further processing of the FRO state before being sampled by a sampling circuit. The FRO state, or simply ring state, can be captured by closing the latches with a capture signal (also referred to herein as an enable signal). The capture signal can also be used to propagate the FRO state data through an exclusive-or (XOR) reduction operation or a hash function to a sampling circuit, such as a sampling flip-flop. As described above, the FRO state can be a cyclic pattern that over time exhibits an increasingly unpredictable error on the phase of the cyclic pattern.

Cryptographic systems need a good source of randomness to be used for key generation or cryptographic challenges. Random number generators have utility in semiconductor cryptographic systems both as entropic sources and as sources for XOR mixing with other entropic sources. A chaotic generator based on a synchronous logic circuit, however, has a property similar to any finite state machine: if both the complete digital state of the generator and the number of synchronous updates is known, all subsequent digital states are easily predicted. Such prediction is contrary to the requirements of a strong cryptographic system.

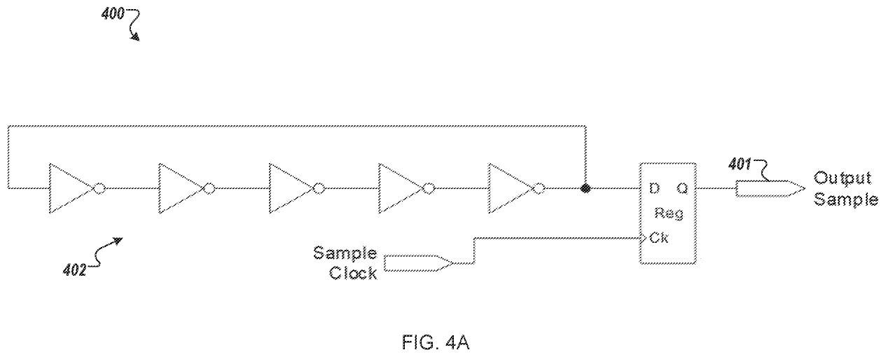

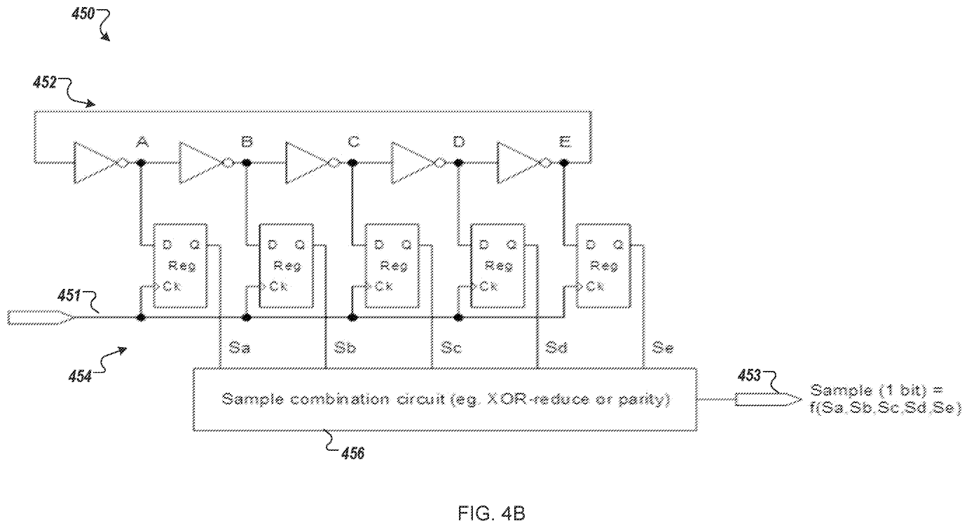

The embodiments described herein are directed to cyclic pattern generation to obtain a random number generator (RNG) with several properties expected of a true random number generator (TRNG). As described above, a TRNG is tied to some random physical phenomena (e.g., transistor offset, thermal noise, phase noise, or the like). A conventional TRNG hardware uses a conventional, inverter-based, FRO as a raw entropy source. The entropy generation model is well understood and required for some security certifications. The inverter-based FRO can be fully digital, but can be relatively slow compared to the embodiments described herein because the circuitry needs to wait for the FRO phase to accumulate sufficient jitter as described below with respect to FIG. 4A. A flip-flop can be coupled to an output of one of the inverters in the ring oscillator to sample an FRO output of the inverter-based FRO. Alternatively, multiple flip-flops can couple to the ring oscillator such that each flip-flop is coupled to an output of each inverter in the ring oscillator to sample an FRO state of the ring oscillator. This can improve entropy collection rate, but can present other challenges with respect to design size and sampling timing accuracy requirements. The embodiments described herein can include a FRO using latches instead of inverters. In addition to be used to for the FRO function, the latches are also used to capture the FRO state of the FRO. Capturing the FRO state, as opposed to the FRO output allows faster entropy generation. Using latches, instead of flip-flops to capture the FRO state can also save on a number of gates, alleviating timing constraints that represent a challenge during layout. For example, by arranging a number of latches in a looping sequence with each latch's inverting output coupled to an input of the next latch in the looping sequence, and controlling a sample window with a sampling signal intrinsically asynchronous to the operation of the FRO, a random number generator with good entropic performance, low power consumption, and suitable for Very Large Scale Integration (VLSI) can be achieved. It should be noted that although the sample window is controlled, the state of each latch is free-running, where the latch acts as an inverter in an open state, and the state of each latch is captured by closing the latch. Alternatively, additional digital logic can be used to further process and sample cyclic patterns using other techniques.

As described herein, the randomness of a random number generated by the embodiments described herein is based on the noise (e.g., quantum level) generated in each of the latches organized in the looping sequences while switching. By sampling the FRO state (individual changes at each latch), the embodiments described herein can accumulate sufficient noise (e.g., jitter) faster than inverter-based FRO entropy sources that sample the FRO output as described in more detail herein. The embodiments described herein may be used for various cryptographic applications, such as seeds for cryptographic generation or key generation. The embodiments of the latch-based FRO can be built using ordinary VLSI circuits found in everyday standard-cell libraries. The embodiments described herein provide a fully synthesizable, random number generator. The FRO and output circuits can be all-digital circuits, can be built using standard-cell gates, can be auto placed and routed (P&R'd) without requiring hand-tuning and hand-layout, and can be tested using low-cost, all-digital manufacturing tests. The embodiments may have very fast startup time because there is no preconditioning of the circuit. The embodiments can have a high-bandwidth at very low power. The actual performance is dependent on the technology in which the FRO is implemented as the noise component in the switching of the latches, is governed by technology parameters. Compared to the inverter-based FRO entropy sources described with respect to FIG. 4A, sampling only a single location in the FRO, the proposed embodiments are significantly faster, comparable to the performance that could be achieved with inverter-based FRO entropy source sampled at every inverter output. As the circuit is all-digital, the embodiments also consume very little standby power, limited only by the leakage current of the standard cell gates. The embodiments may tradeoff sample rate for the amount of entropy per bit. The latch-based FRO for the RNGs described herein is a good entropy source and can be used in connection with other cryptographic operations to improve the amount of entropy per output bit. For example, two or more bits can be mixed (e.g., combined via at least one XOR gate) for improving the amount of entropy per output bit.

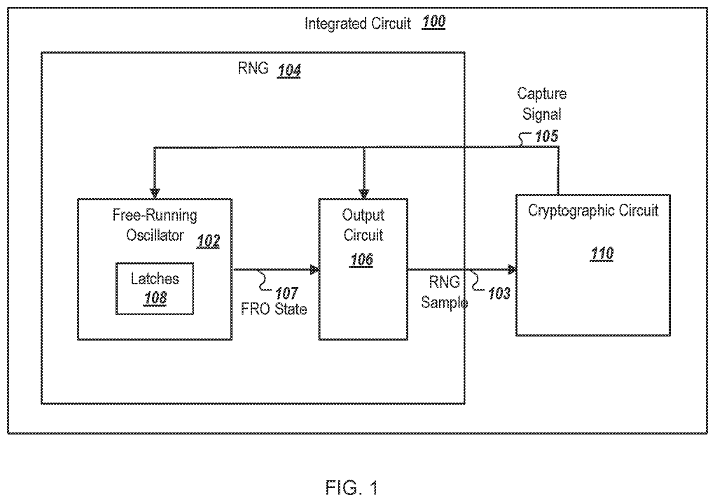

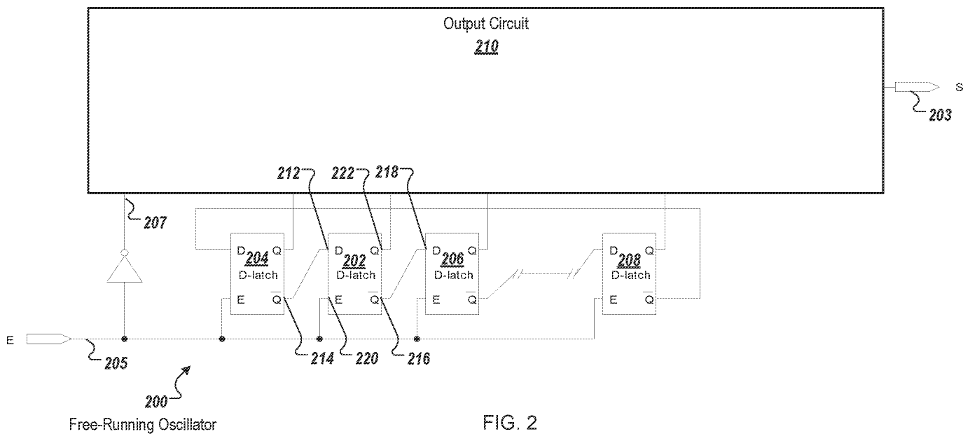

FIG. 1 is a schematic diagram of an integrated circuit 100 with a latch-based free-running oscillator (FRO) 102 to generate a random digital value 103 according to one embodiment. The latch-based FRO 102 can be part of random number generator (RNG) 104 that also includes an output circuit 106 that is coupled to the latch-based FRO 102. The output circuit 106 can include a combinatorial circuit and a sampling circuit to generate the random digital value 103. The combinatorial circuit can implement a XOR reduction function, a hash function, or the like, to determine an unpredictable output value derived from the unpredictable FRO state of the FRO state. The latch-based FRO 102 includes a chain 108 of latches, each latch having an input, a non-inverting output, and an inverting output as illustrated. The non-inverting output of a latch is coupled to an input of a next latch, forming a looping sequence. For example, an input of a first latch is coupled to an inverting output of a second latch that is earlier in the looping sequence and an inverting output of the first latch is coupled to an input of a third latch that is later in the looping sequence. In one embodiment, the looping sequence is a ring topology in which a last latch in the chain is coupled to a first latch in the chain to create a ring oscillator. In other embodiments, each latch has a single inverting or non-inverting output. This depends on the target technology. In either embodiment, in the combined ring, the signal is always inverted an odd number of times, at least once, at most at every latch, provided an odd number of latches is used in the combined ring. The FRO state can be taken from the same output that is also propagated to the input of the next latch, or it can be taken from the ‘other’ latch output, if available. The second approach is better from a technical perspective but not absolutely required for the circuit to operate. The ring oscillator can operate as the FRO in a first mode and can capture a ring state of the latch-based FRO 102 in a second mode. That is, the individual latches of the chain 108 can be activated to store the latch's current state. As illustrated, the latch-based FRO 102 can receive a capture signal 105 that can capture a FRO state 107 of the chain 108 of latches. Additional details of the chain 108 of latches are described below with respect to FIG. 2.

The output circuit 106 is coupled to the latch-based FRO 102. The output circuit is configured to receive the ring state, FRO state 107, determine an unpredictable output value derived from the unpredictable FRO state (i.e., output value) of the ring state, and output the random digital value 103 based on the unpredictable output value. The FRO state 107 can be a multi-bit number, each bit representing a tap in the chain. That is, each latch can output on the non-inverting input a number for the respective bit. The random digital value 103 can be a RNG sample that is captured, for example, by a sampling flip-flop. The sampling flip-flop can be controlled by a system clock that is independent from the capture signal 105. The output circuit 106 is coupled to the outputs of the latches in the chain 108 of latches and can capture the FRO state 107 output from the latch-based FRO 102 in response to the capture signal 105. The capture signal 105 can be a control signal and can also be referred to as a capture/pass signal (or C/P signal). For example, when “Pass” is active (capture not active), each latch in the chain 108 of latches is transparent, and the entropy generation is active. Entropy generation is done by accumulating jitter on the phase of the oscillation signal in the latch-based FRO 102. When sampled, the accumulated jitter has resulted in a certain level of uncertainty about the precise phase of the signal (also referred to herein as FRO state), which causes a level of uncertainty in the actual value of the sampled signal. It is this uncertainty that is expressed in terms of entropy of the output sample. When “Capture” is active, the latches in the latch-based FRO 102 capture their current state, entropy generation stops, and the captured state can be sampled by a sampling circuit. Note that the entropy of the random digital value 103 is based on both the entropy generation by the chain 108 of latches, as well as the metastability of the latches in the chain 108 experienced during a transition from “Pass” to “Capture.” The RNG 104 can include multiple instances of the latch-based FRO 102 and the output circuit 106. For example, the RNG 104 can include 8 instances and output an 8-bit digital value, where the random digital value 103 is one bit of the 8-bit number. The output circuit 106 can include other circuitry to further randomize the random number generation.

As illustrated in FIG. 1, the capture signal 105 can originate from a cryptographic circuit 110 that requests a random number from the RNG 104. The cryptographic circuit 110 can send the capture signal 105 to the RNG 104 and can receive the random digital value 103 in response. Alternatively, the capture signal 105 can originate from circuitry within the RNG 104 and the RNG 104 can receive a request (e.g., a command or a signal) for a random number from the cryptographic circuit 110 and the RNG 104 can return the random number to the cryptographic circuit 110. Alternatively, the capture signal 105 can be received from an application or other software executed by the integrated circuit 100, such as by a processor core of the integrated circuit 100.

FIG. 2 is a schematic diagram of a FRO 200 with a set of latches organized in a looping sequence to generate a random digital value according to one embodiment. The set of latches operate as a FRO while the latches operate in the first mode and capture a ring state of the FRO when the latches operate in a second mode. To form a looping sequence, an input 212 of a first latch 202 is coupled to an inverting output 214 of a second latch 204 that is earlier in the looping sequence and an inverting output 216 of the first latch 202 is coupled to an input 218 of a third latch 206 that is later in the looping sequence. Each of the non-inverting outputs of the set of latches is coupled to an output circuit 210. The output circuit 210 is configured to receive the ring state of the FRO 200 and a capture signal 205 or an inverted capture signal 207 as illustrated in FIG. 2. The output circuit 210 is configured to determine an unpredictable output value of the ring state and generate a random digital value 203 based on the unpredictable output value. The output circuit 210 can output the random digital value 203 to another circuit.

As illustrated in FIG. 2, the set of latches can include any number of latches, as illustrated by an Nth latch 208, where N is a positive integer. It should be noted that when N is an even number, the set of latches still need to have an odd number of inversions of the signal happening on every ring transition or the ring will not oscillator. In one embodiment, the set of latches includes an odd number of latches. The odd number of inverters can contribute to entropy generation. As described herein, the FRO 200 is configured to receive the capture signal 205. The FRO 200 is configured to permit cyclic pattern generation when the capture signal 205 is not active and to stop the cyclic pattern generation when the capture signal 205 is active. The capture signal 205 can also be used by the latches to capture its respective state and the set of latches output a ring state (also referred to herein as FRO state) to the output circuit 210. The output circuit 210 can include a sampling circuit to sample a representation of the FRO state, such as by capturing an unpredictable output value of the FRO state, as described herein. In one embodiment, the output circuit 210 includes an XOR reduction circuit coupled to each of the taps of the set of latches. The XOR reduction circuit is configured to determine a parity value of the ring state and output the random digital number based on the parity value. In another embodiment, the output circuit includes a hash function that receive the ring state and outputs the random digital value based on the ring state. In one embodiment, the output circuit 210 includes digital logic circuitry that is configured to determine the unpredictable output value of a state of outputs of the set of latches in the FRO 200 and generate a random digital number sample while the latches operate in a latch mode.

As illustrated in FIG. 2, the FRO 200 includes at least the first latch 202, the second latch 204, and the third latch 206. The first latch 202 includes the input 212, the inverting output 216, an enable input 220, and a non-inverting output 222. As described above, the input 212 is coupled to the inverting output 214 of the second latch 204 and the inverting output 216 is coupled to the input 218 of the third latch 206. The enable input 220 is configured to receive the capture signal 205. In a transparent mode, the first latch 202 is configured to propagate a state of the input 212 to the non-inverting output 222 directly, and in the inverted form to the inverting output 216. The first latch 202 is in the transparent mode when the capture signal 205 is inactive. When the capture signal 205 is active, the first latch 202 is configured to stop propagating the state of the input 212 to the non-inverting output 222 or the inverting output 216. When the capture signal 205 is active, the latches operate in a latch mode. While in the latch mode, the output circuit 210 can now use stable signals to calculate the output value 203. The final input state of the first latch 202 is one bit that is used for generating the random digital number sample by the output circuit 210. The output circuit 210 can be configured to sample and hold the output value 203 as a random digital number sample.

It should be noted that if there were only three latches in the chain, the non-inverting output of the third latch 206 would be coupled to an input of the second latch 204. If there are more latches than three, then the non-inverting output of the Nth latch 208 is coupled to the input of the second latch 204.

In the depicted embodiment, the FRO 200 includes a chain of latches that is organized in a ring topology and forms an N-bit ring state and the output circuit 210 captures the N-bit ring state as the basis for the random digital value 203. The N-bit ring state can be used to generate one or more bits of an M-bit RNG sample. In some cases, N and M are equal. In other cases, N and M are not equal. In another embodiment, the chain of latches can be organized in other looping sequences. As depicted, the latches in the chain are arranged in a looping sequence (e.g., ring oscillator) in which the second latch 204 is directly adjacent to the first latch 202 in one direction in the looping sequence and the third latch 206 is directly adjacent to the first latch 202 in another direction in the looping sequence. A respective one of the latches may be coupled to a first directly adjacent latch in the looping sequence and to a second directly adjacent latch in the looping sequence. The second, first, and third latches may be located sequentially adjacent to one another in physical space. In other embodiments, the second, first, and third latches may be located apart (non-sequentially) to one another in physical space. For example, there may be one or more intervening latches in between the second and first latches and one or more intervening latches in between the first and third latches

In another embodiment, the latches in the chain are arranged in a looping sequence (e.g., ring topology) in which the second latch is not directly adjacent to the first latch but precedes the first latch in one direction in the looping sequence and the third latch is not directly adjacent to the first latch but succeeds the first latch in another direction of the looping sequence. The second latch may precede the first latch in the ring topology and the first latch precedes the third latch in the ring topology. In another embodiment, the second latch is at least two positions away from the first latch in a first direction of the ring topology and the third latch is at least two positions away from the first latch in a second direction of the ring topology. Alternatively, the latches may be configured in other looping sequences, such as a daisy-chain configuration.

The latches of the FRO 200 are digital latches and can be built using a standard-cell library. In semiconductor design, standard cell methodology is a method of designing application-specific integrated circuits (ASIC) with mostly digital-logic features. For example, each latch may be made up of about ten NAND gate equivalents of a standard-cell library.

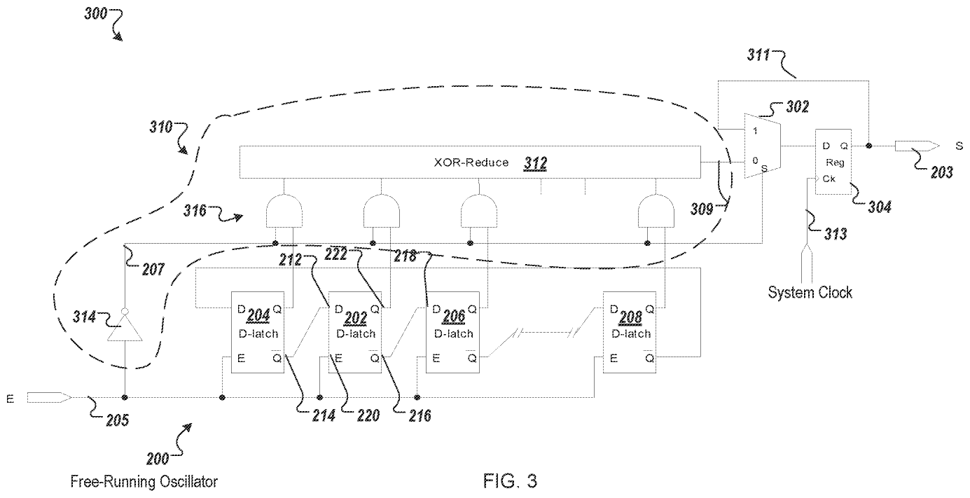

FIG. 3 is a schematic diagram of an output circuit 300 coupled to the FRO 200 with a set of latches according to one embodiment. The FRO 200 of FIG. 3 is similar to the FRO 200 of FIG. 2 as designated by the same reference labels. The output circuit 300 includes digital logic circuitry 310, a multiplexer 302 coupled to an output 309 of the digital logic circuitry 310, and a flip-flop 304 with an input coupled to an output of the multiplexer 302. The multiplexer 302 is configured to receive an output 311 of the flip-flop 304 and the output 309 of the digital logic circuitry. The multiplexer 302 is configured to select the output 309 of the digital logic circuitry 310 when the capture signal 205 is active and the latches operate in the latch mode. The flip-flop 304 can be clocked by a system clock 313. The system clock 313 can be independent of the capture signal 205.

As illustrated in FIG. 3, the digital logic circuitry 310 includes an XOR reduction circuit 312 coupled to the set of latches. The XOR reduction circuit 312 is configured to determine the parity value of the ring state and output the random digital number based on the parity value. The multiplexer 302 is configured to receive an output of the flip-flop 304 and the output of the XOR reduction circuit 312. The multiplexer 302 is configured to select the output of the XOR reduction circuit 312 when the capture signal 205 is active and the latches operate in the latch mode.

Also, as illustrated in FIG. 3, the digital logic circuitry 310 can include an inverter 314 and a set of logic gates 316, such as the AND logic gates illustrated in FIG. 3. The inverter 314 receives the capture signal 205 and generates the inverted capture signal 207. The set of logic gates 316 are coupled to the set of latches and the XOR reduction circuit 312. Each of the set of logic gates 316 is coupled to one of the non-inverting outputs of the set of latches and the capture signal 205. When the capture signal 205 is active, the set of logic gates 316 outputs output states to the XOR reduction circuit 312. The XOR reduction circuit 312 outputs the output 309 that is indicative of the FRO state and the multiplexer 302, in response to the capture signal 205, passes the output 309 to the flip-flop 304 to be sampled according to the system clock 313. When the capture signal 205 is not active, the multiplexer 302 passes the output 311 of the flip-flop 304 to the input of the flip-flop 304. The flip-flop outputs the random digital value 203. The random digital value 203 can be a single bit of a stream of bits, a single bit of multiple bits from multiple FROs, or the like. As described above, the capture signal 205 can be received from an external circuit (e.g., a synchronous processor that requires random values for some operation). It should be noted that the digital logic circuitry 310 can be used to limit signal propagation from the latch outputs through the XOR reduction circuit 312, while the FRO is running. This can be done to limit power consumption but is not strictly part of the entropy generation circuitry.

In a further embodiment, the output 309 or the random digital value 203 can be combined with an output of one or more other random number generators provided by a vendor of an integrated circuit (IC) in which the FRO 200 is implemented. That is, in one embodiment, an integrated circuit includes an N-bit FRO, such as FRO 200, an ASIC RNG, and mixing logic that mixes the output of the N-bit FRO and the ASIC RNG. The mixing logic may be coupled to an output of the flip-flop 304 that capture the random digital value 203 and to an output of the ASIC RNG. The mixing logic combines the two values (e.g., via an XOR operation) to generate a new random digital value. Note that this combination of two values could be done within the output circuit 300 itself. For example, two 8-bit RNG circuits could be built, each having a FRO, and their 16-bit output combined via an 8-bit XOR into a single 8-bit result. Alternatively, the 8-bit digital RNG can be used as a seed to the ASIC RNG and contributes to the entropic performance of the ASIC RNG. This technique of combining RNGs is generally practiced so that random values can still be generated even if an attacker has disabled some-but-not-all of the random generators. In a further embodiment, the output states from the individual latches can also be mixed with other values from other sources.

As described herein, the generation of truly unpredictable random numbers is essential to the security of many information systems making use of cryptographic primitives to protect their information and operation. Typical implementations of digital true random number generators use one or more ‘digital free-running oscillators’ which by their nature, produce a ‘jittery’ output signal that is sampled at regular intervals to produce unpredictable (hence random) output bits.

Typical entropy generation blocks used in cryptographic True-Random Number generators, are built by sampling the output of one or more digital inverter-based Free-Running Oscillators at certain sampling intervals, such as illustrated in FIG. 4A as FRO 400.

FIG. 4A is a schematic diagram of a conventional, inverter-based FRO 400 and a single sampling circuit according to one implementation. Entropy is generated by the channel noise present in the Complementary metal-oxide-semiconductor (CMOS) transistors used in the inverter cells 402, which after time leads to an increasing amount of jitter on the output signal of the FRO 400. The presence of this jitter makes the value that is captured when sampling the FRO output at a given time, unpredictable. The level of unpredictability of the captured sample (to an outside observer) is expressed as its ‘entropy level’. The entropy level is directly related to the ratio between the standard deviation for the jitter present and the frequency at which the value that is sampled. The frequency potentially changes as there needs to be a significant chance that the jitter on the output signal 401 causes the state of the sampled signal to change ‘beyond’ the sampling point, making it unpredictable which state (‘1’ or ‘0’) is captured at the time of sample. The more unpredictable this state is (in other words, the closer the change of sampling a ‘1’ or a ‘0’, approaches 0.5 (50%)) the better the ‘entropy level’ in the sample. Since the standard deviation of the jitter in an FRO grows monotonically and proportional to the square root of time, starting at zero jitter from the previous sample, it is beneficial to sample the output of a FRO switching at very high frequency (i.e. sample a signal that has its state changes close together in time). FRO frequency however is limited by technology. If the FRO frequency is set too high, the FRO may stop oscillating altogether, or may become unreliable over the lifecycle of the device due to increased aging of the frequently switching digital cells.

Unlike the FRO in FIG. 4A, aspects of the present disclosure change the approach of sampling the ring oscillator at a single point, instead capturing the state of every cell in the FRO itself as described herein. This captured state can then be combined by a combinatorial circuit into a single output bit. The benefit of this approach is that the single output bit state now changes with every state change in the ring oscillator, which happens every time the next cell in the ring switches state — effectively every ‘propagation delay time (d)’ of the used cell. Hence, this leads to a significantly higher switching frequency for the ‘sampled’ bit in this approach (effectively, f=½d) compared to the situation that sampling is only done at a single point in the ring (which has a switching frequency of f=1/(2Nd) with N being the number of inverters in the ring.) Due to this higher switching frequency in the sampled signal, a much smaller amount of jitter will already cause unpredictability in the state of the sampled bit, hence the number of samples with good entropy that can be captured per second, is much higher. Capturing the state of every cell in the ring can be done in a straightforward way by placing a capture flip-flop at every node in the oscillator ring, such as illustrated in FRO 450 of FIG. 4B.

FIG. 4B is a schematic diagram of an inverter-based FRO 450 and multiple sampling circuits according to another implementation. The FRO 450 is a straightforward method of capturing the state of the ring at every FRO cell. The FRO 450 includes the inverter cells 452 and a set of flip-flops 454, each coupled to an output of the inverter cells 452. The set of flip-flops 454 are clocked by an input signal 451. The output of the flip-flops 454 are received by a sample combination circuit 456 (e.g., XOR-reduce for a parity value or other functions generating unpredictable output values from the unpredictable sample input) that outputs a single bit 453. The FRO 450 can have a drawback in that it adds a significant amount of area to the design because of the set of flip-flops 454. In addition, to making sure the ‘state changes’ are captured accurately in time (to prevent bias in the captured bits), the signal propagation delay from every inverter cell, to its capturing flip-flop, must be made equal, which presents a significant challenge during the “place and route” stage of the design.

The embodiments describe herein improve on the idea of digital FRO by not just capturing the output of the FRO, but also by capturing the complete state of the ring, which allows for a significantly higher sample rate while producing the same amount of entropy per sample. In addition, the latch-based method used for capturing the state of the ring, reduces the amount of gates needed when compared to a straightforward method of capturing the data by adding a capture flip-flop at every output of every FRO element. Finally, the latch-based method removes the requirement to balance the signal propagation delay from each FRO element to each capturing flip-flop that arises when using the straightforward flip-flop based approach. This in turn makes the embodiments described herein much easier to implement in an actual System on Chip. By combining the flip-flop capture function and the inverter function of the FRO cells into latches as described herein, the aforementioned drawbacks are addressed. Instead of using inverter cells to build the FRO, aspects of the present disclosure use latch cells in a latch-based FRO. A latch cell has two modes: a transparent mode, in which the input signal state is directly propagated to its outputs (both directly and in negated form), and a ‘latch mode’ in which the current state of the latch's output, is frozen. The latched-based FRO operates by initially setting all latches in the ring, in transparent state, which effectively creates a FRO again. To sample the state of the ring, the latches are temporarily placed in ‘latched’ state and the output of the latches is fed to a combinatorial circuit to produce the signal to be sampled. The sampled signal obviously changes depending on the output state of the latches, which change every latch propagation delay. The combinatorial circuit can be a sample combination circuit that implements an XOR-reduce function or another type of parity value functions. An example output can be expressed as follows: Sample (1 bit)=f(Sa,Sb,Sc,Sd,Se).

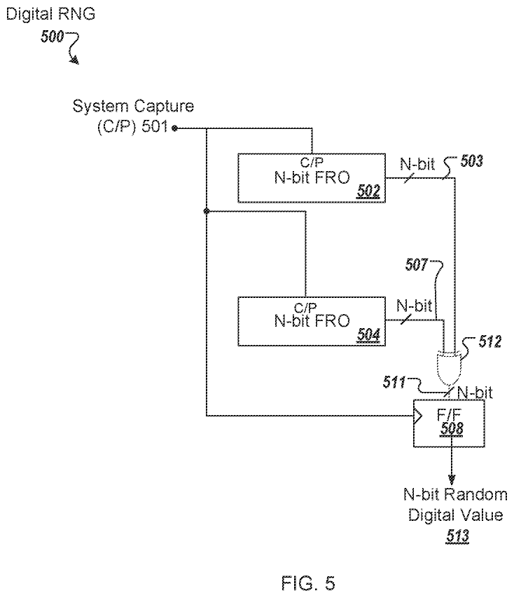

FIG. 5 is a schematic diagram of a digital RNG 500 including two N-bit FROs according to one embodiment. The digital RNG 500 includes a first N-bit FRO 502, where N is a positive integer. The first N-bit FRO 502 receives a system capture/pass (C/P) signal 501. More specifically, each latch in the chain of latches in the first N-bit FRO 502 is configured to receive the system C/P signal 501. These latches will capture and hold a first N-bit value 503 when the system C/P signal 501 is active (i.e., capture signal). As described above, the entropy of the first N-bit value 503 is based on the free-running oscillation of the first N-bit FRO 502 as well as the metastability of the latches. The digital RNG 500 also includes a second N-bit FRO 504. Each latch in the chain of latches in the second N-bit FRO 504 is configured to receive the system C/P signal 501. These latches will capture and hold a second N-bit value 507 when the system C/P signal 501 is active (i.e., capture signal). In another embodiment, one of the outputs of the first N-bit FRO 502 can be combined with a gate to supply a second capture/pass signal to the second N-bit FRO 504. In this way, the second N-bit value's capture and generation phases can be unpredictably controlled by a value from the first N-bit's capture and generation, thereby generating further entropy. In addition to this new mechanism, the entropy of the second N-bit value 507 is based on the free-running oscillation of the second N-bit FRO 504 as well as the metastability of the latches. XOR logic gate 512 is coupled to receive the first N-bit value 503 and the second N-bit value 507 and outputs a third N-bit value 511, which is then captured by a sampling flip-flop (FF) 508. The XOR logic gate 512 performs an XOR operation on the first N-bit value 503 and the second N-bit value 507 to generate the third N-bit value 511 that is latched by the FF 508 when the capture signal 501 transitions from inactive to active (note that there may need to be a small delay (not shown) inserted between the capture signal 501 and the clock input of FF 508). An output of the sampling FF 508 is an N-bit random digital value 513. In a further embodiment, the N-bit random digital value 513 can be an input to the output circuit 300 described above. In another embodiment, the N-bit random digital value 513 can be an input to a XOR reduction function or a hash function. Alternatively, the N-bit random digital value 513 can be mixed with other values, as described herein. For example, mixing logic is coupled to receive the N-bit random digital value 513 and a random number from another RNG provided by a vendor of an IC in which the digital RNG 500 is implemented. The mixing logic is configured to mix the N-bit random digital value 513 with the random number from the RNG to generate another random number.

In one embodiment, the digital RNG 500 may be used within a security core within an integrated circuit. For example, a system-on-chip (SoC) may have one or more processor cores, memory, as well as other functional units. The SoC also includes a security core and secure memory. The security core may include a challenge generator that generates a challenge based on a preshared key, for example. The preshared key can be mixed with a random digital value to create a random challenge to authenticate another entity that knows the preshared key in a challenge-response authentication process. In one embodiment, the digital RNG 500 is part of the cryptographic product that can rely on a RNG provided by an ASIC partner to mix with a random digital value from the digital RNG 500 to generate the random challenge. Alternatively, the digital RNG 500 may be part of other cryptographic systems, and can be used in other applications than random challenges. The digital RNG 500 can provide the necessary amount of randomness, as measured by an entropy metric, for the security core. The random digital value generated by the digital RNG 500 could also be used without mixing with the ASIC partner's RNG. The digital RNG 500 is an all-digital circuit implementation, built using standard-cell gates. The digital RNG 500 can be automatically placed and routed using automation tools, requiring less hand-tuning and hand-layout, or no hand-tuning and hand-layout of the circuit. The digital RNG 500 can be tested using low-cost, all-digital manufacturing tests.

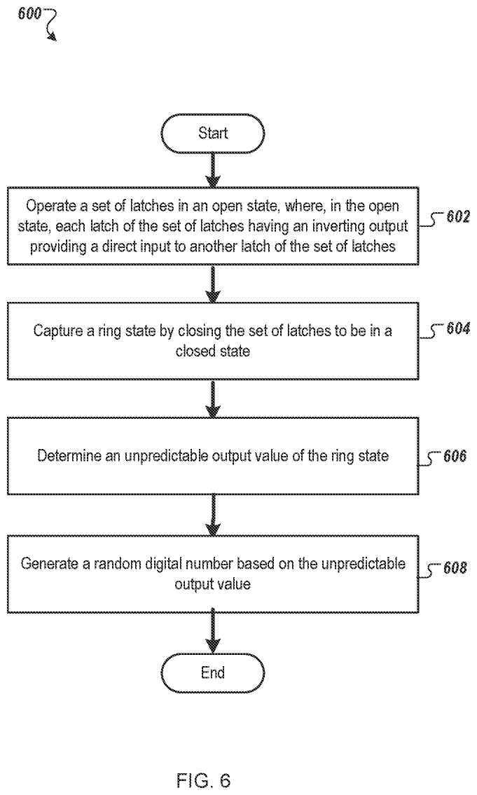

FIG. 6 is a flow diagram of a method 600 of generating a random digital value using a latched-based FRO according to one embodiment. The method 600 may be performed by any of the latch-based FROs described herein or the RNGs with latch-based FROs described herein.

The method 600 begins with operating a set of latches in an open state, where, in the open state, each latch of the set of latches has an inverting output providing a direct input to another latch of the set of latches (block 602). The method 600 captures a ring state by closing the set of latches to be in a closed state (block 604). The ring state includes an output from each of the set of latches. The method 600 determines an unpredictable output value of the ring state (block 606) and generates a random digital number based on the unpredictable output value (block 608). The method 600 can continue or stop based on the number of bits needed by a requesting circuit.

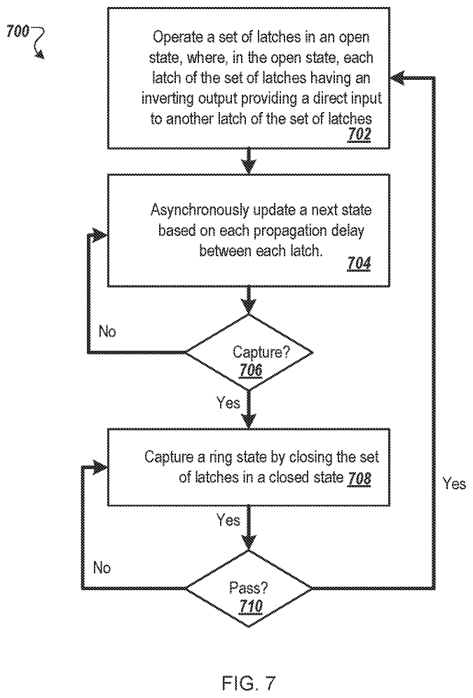

FIG. 7 is a flow diagram of a method 700 of generating a random digital value using a latched-based FRO according to another embodiment. The method 700 may be performed by any of the latch-based FROs described herein or the RNGs with latch-based FROs described herein.

The method 700 begins with operating a set of latches in an open state, where, in the open state, each latch of the set of latches has an inverting output providing a direct input to another latch of the set of latches (block 702). The method 700 asynchronously updates a state of the set of latches based on each propagation delay between each latch (block 704). The method 700 determines if a capture signal is received (block 706). If no capture signal is received at block 706, the method 700 returns to block 704 to continue updating the state. Once the capture signal is received at block 706, the method 700 captures a ring state by closing the set of latches to be in a closed state (block 708). The ring state can be input into a combinatorial circuit, such as described herein. The method 700 then determines whether a pass signal is received at block 710. The pass signal can be the inverse of the capture signal. If no pass signal is received, the ring state is held until the pass signal is received at block 710, returning the method 700 back to block 702. In one embodiment, at block 708, the method 700 also determines a unpredictable output value of the state of the set of latches. This can be done by performing a XOR reduction of the state, a hash function of the state, or the like. The method 700 can also generate the random digital value based on the unpredictable output value.

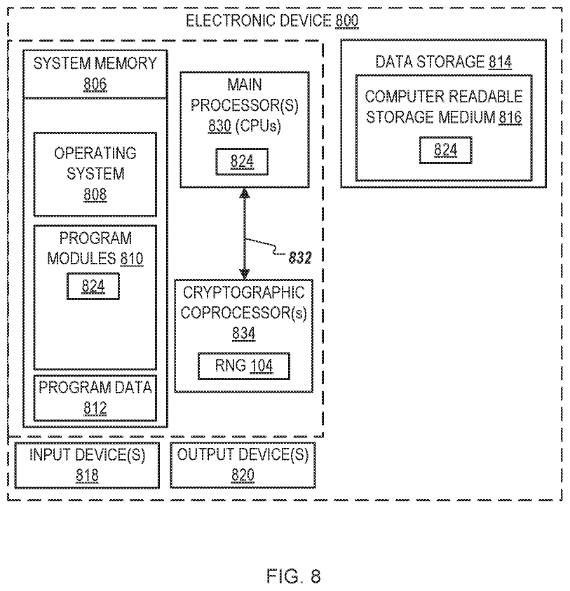

FIG. 8 is a block diagram of an electronic device 800, including a RNG with a latch-based FRO for a cryptographic operation of a cryptographic process according to one embodiment. The electronic device 800 may be connected to other computing devices in a LAN, an intranet, an extranet, and/or the Internet. The electronic device 800 may operate in the capacity of a server machine or a client machine in a client-server network environment. The electronic device 800 may be provided by a personal computer (PC), a mobile device, a set-top box (STB), a server, a network router, switch or bridge, or any machine capable of executing a set of instructions (sequential or otherwise) that specify actions to be taken by that machine. Further, while only a single electronic device 800 is illustrated, the terms “electronic device” or “computing system” shall also be taken to include any collection of computing devices that individually or jointly execute a set (or multiple sets) of instructions to perform the methods described herein. Alternatively, the electronic device 800 may be other electronic devices, as described herein.

The electronic device 800 includes one or more processor(s) 830, such as one or more CPUs, microcontrollers, field programmable gate arrays, or other types of processors. The one or more processor(s) 830 can include one or more processing cores. The electronic device 800 can also include one or more cryptographic processor(s) 834. The cryptographic processor(s) 834 can be dedicated processing logic comprising hardware, software, firmware, or any combination thereof for handling computations, including computations for a cryptographic process. The cryptographic process can be performed by the processor(s) 830 as the main processor and can issue one or more instructions 832 to the cryptographic processor(s) 834 for computations. These computations can include generating a random number by a RNG, such as the RNG 104 of FIG. 1 or the other circuits described herein that use the latch-based FRO. The electronic device 800 also includes system memory 806, which may correspond to any combination of volatile and/or non-volatile storage mechanisms. The system memory 806 can include synchronous dynamic random access memory (DRAM), read-only memory (ROM), flash memory, internal or attached storage devices, or the like. The system memory 806 stores information that provides operating system component 808, various program modules 810, program data 812, and/or other components. In one embodiment, the system memory 806 stores instructions of methods to control operation of the electronic device 800. The electronic device 800 performs functions by using the processor(s) 830 to execute instructions provided by the system memory 806. In one embodiment, the program modules 810 may include an application 824. The application 824 can request a cryptographic operation in which a random number is generated by the RNG 104. The electronic device 800 may perform some or all of cryptographic operations of a cryptographic process described herein, including generating a random digital value such as described above in the method 600 described in connection with FIG. 6 or the method 700 described in connection with FIG. 7. Alternatively, the random number can be generated in connection with non-cryptographic operations.

The electronic device 800 also includes a data storage device 814 that may be composed of one or more types of removable storage and/or one or more types of non-removable storage. The data storage device 814 includes a computer-readable storage medium 816 on which is stored one or more sets of instructions embodying any of the methodologies or functions described herein. While the computer-readable storage medium 816 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding, or carrying a set of instructions for execution by the machine and that cause the machine to perform the methods described herein. The term “computer-readable storage medium” shall accordingly be taken to include, but not be limited to, solid-state memories, optical media, and magnetic media. Instructions for the program modules 810 may reside, completely or at least partially, within the computer-readable storage medium 816, system memory 806 and/or within the processor(s) 830 during execution thereof by the electronic device 800, the system memory 806 and the processor(s) 830 also constituting computer-readable media. The instructions may further be transmitted or received over a network via a network interface device. The network interface device can communicate with one or more devices over wired or wireless connections. The network interface device can communicate over a private network, a public network, or any combination thereof. The electronic device 800 may also include one or more input devices 818 (keyboard, mouse device, specialized selection keys, etc.) and one or more output devices 820 (displays, printers, audio output mechanisms, etc.). The electronic device 800 can include other components, such as video display units, input devices, and signal generation devices. These components can be integrated into one or many components.

In the above description, numerous details are set forth. It will be apparent, however, to one of ordinary skill in the art having the benefit of this disclosure, that embodiments of the present invention may be practiced without these specific details. In some instances, well-known structures and devices are shown in block diagram form, rather than in detail, in order to avoid obscuring the description.

Some portions of the detailed description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “encrypting,” “decrypting,” “storing,” “providing,” “deriving,” “obtaining,” “receiving,” “authenticating,” “deleting,” “executing,” “requesting,” “communicating,” or the like, refer to the actions and processes of a computing system, or similar electronic computing device, that manipulates and transforms data represented as physical (e.g., electronic) quantities within the computing system's registers and memories into other data similarly represented as physical quantities within the computing system memories or registers or other such information storage, transmission or display devices.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this disclosure, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this disclosure and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such.

Embodiments described herein may also relate to an apparatus for performing the operations herein. This apparatus may be specially constructed for the required purposes, or it may comprise a general-purpose computer selectively activated or reconfigured by a computer program stored in the computer. Such a computer program may be stored in a non-transitory computer-readable storage medium, such as, but not limited to, any type of disk including floppy disks, optical disks, CD-ROMs and magnetic-optical disks, read-only memories (ROMs), random access memories (RAMs), EPROMs, EEPROMs, magnetic or optical cards, flash memory, or any type of media suitable for storing electronic instructions. The term “computer-readable storage medium” should be taken to include a single medium or multiple media (e.g., a centralized or distributed database and/or associated caches and servers) that store the one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The algorithms and displays presented herein are not inherently related to any particular computer or other apparatus. Various general-purpose systems may be used with programs in accordance with the teachings herein, or it may prove convenient to construct a more specialized apparatus to perform the required method steps. The required structure for a variety of these systems will appear from the description below. In addition, the present embodiments are not described with reference to any particular programming language. It will be appreciated that a variety of programming languages may be used to implement the teachings of the embodiments as described herein.

The above description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth above are merely exemplary. Particular implementations may vary from these exemplary details and still be contemplated to be within the scope of the present invention.

It is to be understood that the above description is intended to be illustrative and not restrictive. Many other embodiments will be apparent to those of skill in the art upon reading and understanding the above description. The scope of the invention should, therefore, be determined with reference to the appended claims, along with the full scope of equivalents to which such claims are entitled.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

What is claimed is:

1. An integrated circuit comprising:
a set of latches organized to form a ring oscillator in a transparent mode, wherein the ring oscillator comprises an odd number of signal inversions; and
digital logic circuitry coupled to the set of latches, wherein the digital logic circuitry is configured to determine a unpredictable output value of a state of outputs of the set of latches and generate a random digital number sample in a latch mode.

2. The integrated circuit of claim 1, wherein the set of latches comprises a first latch, a second latch, and a third latch, and wherein the first latch comprises:
a first input coupled to a second inverting output of the second latch;
a first inverting output coupled to a third input of the third latch;
an enable input configured to receive a capture signal; and
a first non-inverting output, the first latch to propagate a state of the first input to the first non-inverting output directly and an inverted state of the first input to the first inverting output when the capture signal is inactive in the transparent mode and to stop propagating the state of the first input to the first non-inverting output and the first inverting output when the capture signal is active in the latch mode, wherein the state of the first input is one bit for generating the random digital number sample.

3. The integrated circuit of claim 2, further comprising an output circuit coupled to the digital logic circuitry and configured to sample and hold the random digital number sample.

4. The integrated circuit of claim 3, wherein the output circuit comprises:
a multiplexer coupled to an output of the digital logic circuitry; and
a flip-flop comprising an input coupled to an output of the multiplexer, wherein the multiplexer is configured to receive an output of the flip-flop and the output of the digital logic circuitry, wherein the multiplexer is configured to select the output of the digital logic circuitry when the capture signal is active in the latch mode.

5. The integrated circuit of claim 2, wherein the digital logic circuitry comprises an exclusive OR (XOR) reduction circuit coupled to the set of latches, wherein the XOR reduction circuit is configured to determine a parity value of the state of outputs as the unpredictable output value and output the random digital number sample based on the parity value.

6. The integrated circuit of claim 1, wherein the digital logic circuitry comprises:
an inverter;
a set of AND logic gates; and
an exclusive OR (XOR) reduction circuit coupled to the set of AND logic gates, wherein the inverter is configured to receive a capture signal indicative of the latch mode and output an inverted capture signal, wherein each of the set of latches is configured to receive the capture signal and output a latch state, wherein each of the set of AND logic gates is configured to receive the inverted capture signal and the latch state from one of the set of latches and output a captured logic state, wherein the XOR reduction circuit is configured to determine a parity value of the state of outputs as the unpredictable output value and generate the random digital number sample in the latch mode based on the parity value.

7. An integrated circuit comprising:
a ring oscillator comprising a set of latches arranged in a looping sequence, the ring oscillator to operate as a free-running oscillator (FRO) in a first mode and to capture a ring state of the free-running oscillator in a second mode, wherein an input of a first latch of the set of latches is coupled to an inverting output of a second latch of the set of latches that is earlier in the looping sequence, and wherein an inverting output of the first latch is coupled to an input of a third latch that is later in the looping sequence; and
an output circuit coupled to the ring oscillator, wherein the output circuit is configured to receive the ring state, determine a unpredictable output value of the ring state, and output a random digital value based on the unpredictable output value.

8. The integrated circuit of claim 7, wherein the set of latches comprises an odd number of signal inversions.

9. The integrated circuit of claim 7, wherein the ring oscillator is configured to receive a capture signal, wherein the ring oscillator is configured to permit cyclic pattern generation when the capture signal is not active and to stop the cyclic pattern generation when the capture signal is active.

10. The integrated circuit of claim 7, wherein the output circuit comprises an exclusive OR (XOR) reduction circuit coupled to the set of latches, wherein the XOR reduction circuit is configured to determine a parity value of the ring state as the unpredictable output value and output the random digital value based on the parity value.

11. The integrated circuit of claim 7, wherein the output circuit comprises a hash function to generate the random digital value based on the ring state.

12. The integrated circuit of claim 7, wherein the output circuit comprises:
an exclusive OR (XOR) reduction circuit coupled to the set of latches, wherein the XOR reduction circuit is configured to determine a parity value of the ring state as the unpredictable output value and output the random digital value based on the parity value; and
a flip-flop comprising an input coupled to an output of the XOR reduction circuit, wherein the flip-flop is to output the random digital value when in the second mode.

13. The integrated circuit of claim 12, further comprising:
an inverter coupled to receive a capture signal; and
a set of logic gates coupled to the inverter and the XOR reduction circuit and each of the set of logic gates is coupled to one of the set of latches.

14. An integrated circuit comprising:
a ring oscillator comprising a set of latches arranged in a looping sequence, the ring oscillator to generate a random digital value, wherein a first latch of the set of latches is coupled to a second latch of the set of latches that is earlier in the looping sequence and to a third latch that is later in the looping sequence, wherein the first latch comprises:
a first input coupled to a second inverting output of the second latch;
a first inverting output coupled to a third input of the third latch;
an enable input configured to receive a capture signal; and
a first non-inverting output, the first latch to pass through a state of the first input to the first non-inverting output when the capture signal is inactive and to latch a final input state of the first input on the first non-inverting output when the capture signal is active, wherein the final input state is one bit of the random digital value.

15. The integrated circuit of claim 14, wherein the ring oscillator is configured to implement a free-running oscillator (FRO) function to generate the random digital value.

16. The integrated circuit of claim 14, wherein the set of latches comprises an odd number of latches.

17. The integrated circuit of claim 14, wherein the ring oscillator is configured to permit cyclic pattern generation when the capture signal is not active and to stop the cyclic pattern generation when the capture signal is active.

18. The integrated circuit of claim 14, further comprising a flip-flop to sample and hold the random digital value when the capture signal is active, wherein the flip-flop is clocked by a clock signal that is independent from the capture signal.

19. A method comprising:
operating a set of latches in an open state, wherein, in the open state, each latch of the set of latches having an inverting output providing a direct input to another latch of the set of latches;
capturing a ring state by closing the set of latches in a closed state, wherein the ring state comprises an output from each of the set of latches;
determining an unpredictable output value of the ring state; and
generating a random digital number based on the unpredictable output value.

20. The method of claim 19, wherein determining the unpredictable output value of the ring state comprises performing an exclusive OR (XOR) reduction of the ring state to determine a parity value, wherein generating the random digital number comprises sampling the unpredictable output value.
